(19) United States
(12) Patent Application Publication
(10) Pub. No.: US 2003/0064568 A1
(43) Pub. Date: Apr. 3, 2003

(54) Device comprising electronic components in regions of a layer of semiconducting material insulated from each other and manufacturing process for such a device

(76) Inventors: Benoit Giffard, Genoble (FR); Pierre Gidon, Echirolles (FR)

Correspondence Address: Robert E. Krebs, Thelen Reid & Priest LLP, P.O. Box 640640, San Jose, CA, 95164-0640, US

(21) Appl. No.: 10/313,236

(22) Filed: Dec. 5, 2002

Related U.S. Application Data
(62) Division of application No. 09/762,244, filed on Apr. 13, 2001.
Application No. 09/762,244 is a 371 of international application No. PCT/FR99/02032, filed on Aug. 24, 1999.

(30) Foreign Application Priority Data
Aug. 25, 1998 (FR) 98 10686

(51) Int. Cl. H01L 21/339; H01L 21/76

(52) U.S. Cl. 438/404; 438/405; 438/147

(57) ABSTRACT

The invention relates to a process for manufacturing a device comprising electronic components (20a, 20b) in regions (32a, 32b) of a layer of semi conducting material (12), these regions being insulated from each other. The process comprises the following steps:

a) formation of electronic components (30) in regions of a layer of semi conducting material (12) formed on an electric insulating layer (14),

b) formation of trenches passing through the layer of semi conducting material (12) from one side to the other in order to separate the regions (32a, 32b),

c) filling of the trenches (30) with a fluid filling material, and

d) hardening of the said filling material.

Application to the manufacture of integrated circuits comprising power components.

### TECHNICAL FIELD

This invention relates to an electronic device comprising components formed in regions of a layer of semi conducting material insulated from each other. It also relates to a manufacturing process for such a device.

For the purposes of this invention, an electronic component may be an individual component such as a transistor or a diode, or a set of components, for example such as a logic switching stage, a power switching stage or an amplification stage. In particular, a component may comprise one or several doped areas of the semi conducting substrate.

The invention is generally used in applications to the manufacture of integrated circuits and more particularly for circuits comprising components operating at low voltage, or “power” components, or several power components. Power components means components that can resist high potential differences up to 1000 Volts or more, and/or through which high currents up to several amperes can pass.

### STATE OF PRIOR ART

Manufacturing of integrated circuits is tending towards an increasingly dense integration of components in the form of monolithic sets of components corresponding to increasingly complex functions.

Thus for example, it is desirable to associate logical type components operating at low voltage and power components in the same assembly. This type of association of components integrated in the same semi conducting substrate can cause mutual electrical insulation problems. Electrical insulation constraints may apply to individual components or parts of an integrated circuit.

One first possible way of insulating components is to form doped regions forming inversely polarized N-P junctions in the substrate. This type of insulation is fairly widespread, but can only be used for AC voltages at the component terminals.

Furthermore, insulation by inversely polarized junctions is not efficient for diffusion currents generated by components subject to fast and high amplitude variations of the voltage and current applied to them.

Another possible way of insulating components from each other is to form compartments surrounded by insulating dielectric walls, in the substrate. Compartments with dielectric walls are formed in such a manner that each component or set of components is located in a region of the substrate that is electrically insulated from the other components.

One known embodiment of the principle of insulation by dielectric walls consists of using an SOI (Silicon On Insulator) type substrate on which insulation layers are formed.

An SOI type substrate comprises a layer of silicon located above an insulating layer, for example made of silicon oxide. Trenches are formed in the silicon layer with a sufficient depth to reach the oxide layer. They are then coated with a silicon oxide deposit. Trenches with a coat of silicon oxide thus form lateral dielectric walls of the compartments and the insulating layer of the SOI substrate forms the bottom wall.

The lining of insulation trenches is necessary not only to guarantee electrical insulating properties in the long term, but also to obtain a plane upper surface of the silicon layer. A plane layer is necessary for many applications in which “planar” type manufacturing techniques are used. Micro-electronic processing making use of photographic processes such as photoengraving, is difficult to use on surfaces on which there can be severe planeness defects. Planeness defects are not compatible with photographic processes that usually have a low field depth.

Conventionally, trenches are lined by forming a layer of silicon oxide on the sides of the trenches.

Silicon oxide may be formed by oxidation treatment of the sides of the trenches or it may be deposited using a CVD (Chemical Vapour Deposition) process.

When the trenches are being lined, silicon oxide forms in the trenches, and also on the surface of the silicon layer. Trenches are made to be very narrow, due to the cost of forming the oxide lining and operations for removing the undesirable oxide on the surface of the silicon layer.

However, the narrowness of the trenches causes problems when the trenches are being etched. Control over etching of the trenches becomes more difficult and the etching rate becomes slower if the depth of the trenches is increased, or if their width is reduced.

Furthermore, it is important to check that the opening of the trenches does not get clogged so that the deposition gas, for example silane, can reach the bottom of the trenches.

This difficulty may be overcome by providing the trenches with a “V” section so that they are open by a few degrees. Special measures need to be taken in this case to obtain particular trench profiles.

Another problem encountered with a silicon oxide lining in trenches is that the coefficient of expansion of the material is not the same as the coefficient of expansion of the silicon in the semi conducting layer in which the components are formed.

Mechanical stresses may be generated during the heat treatments applied in different steps in manufacturing of integrated circuits after lining the trenches, due to differences in the expansion of different materials. These stresses may cause defects in components, for example resulting from sliding of structures along semiconductor crystalline planes. Defects in components are harmful to the smooth operation of components and therefore to the manufacturing efficiency of integrated circuits.

To avoid differential expansion of materials, the trenches can be lined by coating the sides of the trenches with a thinner coat of oxide and then filling the trenches with polycrystalline silicon (polysilicon).

Polycrystalline silicon is not an insulator and is formed in the trenches, and also like silicon oxide on the free surface of the silicon layer. Thus, polysilicon, which is not useful in itself to operation of the circuit, must be removed from the surface of the silicon layer in order to complete manufacturing of the integrated circuit.

Polycrystalline silicon is removed from the surface of the silicon layer, for example by a mechanical-chemical treatment that is difficult and expensive.

After removing polycrystalline silicon from the surface of the silicon layer, inter-connection tracks may be formed above this surface to connect components to each other.

However, it is found that the existence of conducting parts above regions comprising components, can locally modify the lateral electric fields between different compartments of the semi conducting layer or between components, particularly for power components. The local increase in electric fields, when it reaches critical field values for the material used, can cause breakdown of the components.

Document (1), defined in the references at the end of this description, describes a glass centrifuging process called SOG (Spin-On Glass) that can give a plane and uniform surface on a substrate that initially includes relief. The thicknesses of the layers of glass obtained by the SOG process are small and cannot solve the problems mentioned above.

Furthermore, the SOG process is not suitable for filling the trenches that cross the silicon layer on SOI type substrates from one side to the other. The polymers contained in this material must be removed by vaporization in order to dry the SOG. This operation can only be performed satisfactorily for thin layers of material, particularly for layers thinner than the depth of the trenches.

### PRESENTATION OF THE INVENTION

The purpose of this invention is to propose a device comprising electronic components in regions insulated from each other, and a manufacturing process for such a device without any of the difficulties mentioned above.

One particular purpose is to propose a device with trenches lined with an insulating material that does not generate high stresses due to differential expansion phenomena.

Another purpose is to propose such a device with improved electrical insulation that is not very sensitive to local non-uniformities of the electric field due to electric conductors.

Another purpose is to propose a process for avoiding the parasite formation of material on a free surface of the device.

Another purpose is to propose a process that is not expensive to implement and is suitable for series production.

In order to achieve these purposes, the invention more specifically relates to a process for manufacturing a device comprising electronic components in regions of a layer of semi conducting material, these regions being insulated from each other, and the process comprising the following steps:

a) formation of electronic components in regions of a layer of semi conducting material formed on an electric insulating layer,

b) formation of trenches passing through the layer of semi conducting material from one side to the other in order to separate the regions,

c) filling of the trenches with a fluid electrically insulating filling material that can be hardened, and

d) hardening of the said filling material,

e) formation of a layer of filling material above a free surface of the layer of semi conducting material, and formation of openings at least in the said layer in order to expose areas of the layer of semi conducting material,

f) formation of conducting tracks connecting components together extending over exposed areas, above the layer of semi conducting material.

The conducting tracks may be designed to connect different components in the same region together, or components forming part of different regions and insulated from each other.

These conducting tracks may also be designed to connect components to connecting terminals of the device.

With the invention, it is possible to make use of the filling material to insulate interconnecting tracks from the semi conducting material layer and move them further away, without an additional step of forming the material. This characteristic also reduces the influence of tracks on electric fields existing between regions on the substrate.

The electrically insulating filling material may be formed according to a specific pattern, particularly at the surface of the layer of semi conducting material. Shaping may be done using standard microelectronic processes.

However, advantageously, a photosensitive filling material can be used and shaped by chemical development after insolation through a mask with an appropriate pattern.

The layer of filling material produced in step e) may be made starting from exactly the same material as that used in step c) or from a different material, and it may be put into place at the same time as step c) or afterwards.

Advantageously, the same material can be used to fill in the trenches and cover the surface of the substrate. The steps in which the material is placed and hardened in the trenches and on the surface of the substrate may then be concomitant.

Furthermore, when the trench filling material is used in sufficient quantities to cover the free surface of the layer of semi conducting material or the substrate, this free surface may also be made plane.

Steps in the process may be performed in the order described above by forming spaces for the trenches in the layer of semi conducting material. The trenches are then etched in these spaces after complete or partial formation of the components. The trenches can then be formed first and the components can be formed later.

For the purposes of the invention, hardening of the filling material means sufficient reduction of its fluidity to guarantee that the material remains in the trenches. However, the filling material may remain sufficiently flexible to absorb stresses due to differential expansion with the semi conducting material.

Furthermore, a fluid material may refer to a material that is made liquid by heating or dissolving in a liquid solvent, or a material formed by a mix of liquids that react together chemically to slowly solidify.

The electrically insulating filling material may be chosen from among polyimides, polyacrylics and silicones.

In particular, the insulating material may be a solid-gel type material.

Depending on the type of material chosen, the filling material may be hardened by evaporation of a solvent contained in the material, or by cross-linking, or by chemical reaction.

Since the filling material is put into place in the liquid state, a plane material surface can be obtained automatically.

Trenches may be filled in a single operation or in a series of steps in which the trenches are partially filled with the fluid filling material alternating with steps in which the said material is hardened.

This process according to the invention is suitable for insulating semiconductor regions with trenches with a depth P such that P>5 μm.

Relatively deep and narrow trenches can be filled by adding filling material in the fluid state, and particularly in the liquid state.

In this respect, note that the trenches may extend at least partly into the electrically insulating layer subjacent to the layer of semi conducting material.

Furthermore, before the trenches are filled, the sides of the trenches may be doped, oxidized and/or coated by a material deposit. These operations are mainly intended to increase the voltage withstand between insulated regions of the semi conducting material layer.

When the components made on the substrate are power or high voltage components, good insulation between the various circuits or components at different voltages is necessary, and it is also necessary to make sure that there is sufficient separation between circuits and interconnections.

One special feature of the invention is that these two functions can be carried out in the same sequence of steps. Fluid material may be deposited in common for the two functions that are a priori independent.

Due to the invention, insulation between the circuits is achieved by the use of an SOI substrate associated with trenches filled with a material deposited in the fluid state.

Insulation between high voltage interconnecting tracks and the substrate surface is also achieved by the material deposited in the fluid state. The use of this type of material can result in thick insulation (for example thicker than 5 μm) that avoids areas with a high electric field in the silicon close to its surface.

The invention also relates to a device comprising a layer of electrically insulating material and a layer of semi conducting material formed on the layer of electrically insulating material. In this device, insulating trenches filled with an electrically insulating filling material pass through the layer of semi conducting material from side to side and have trench sides that delimit regions of the layer of semi conducting material. Furthermore, the filling material is chosen among insulating materials that are liquid in their initial state and can be hardened.

Other characteristics and advantages of this invention will become clear after reading the following description with reference to the figures in the attached drawings. This description is given for illustrative purposes only and is in no way restrictive.

### BRIEF DESCRIPTION OF THE FIGURES

FIG. 1 is a diagrammatic section through part of a substrate in which components are formed,

FIGS. 2A and 2B are diagrammatic sections through part of the substrate in FIG. 1 in which a trench is formed,

FIG. 3 is a diagrammatic section through part of the substrate in FIG. 2A and illustrates one step in the preparation of the trench,

FIG. 4 is a diagrammatic section through part of the substrate in FIG. 3, in which the trench is filled with a filling material,

FIG. 5 is a diagrammatic section through part of the substrate in FIG. 4, illustrating shaping of the filling material,

FIG. 6 is a diagrammatic section through part of the substrate in FIG. 5 illustrating the formation of interconnecting tracks on its surface.

### DETAILED PRESENTATION OF PARTICULAR EMBODIMENTS OF THE INVENTION

The following description applies to a substrate with only a single trench that separates two regions in the substrate, for simplification reasons. However, a plurality of trenches may be provided to separate and isolate several regions in the same substrate, and in different directions.

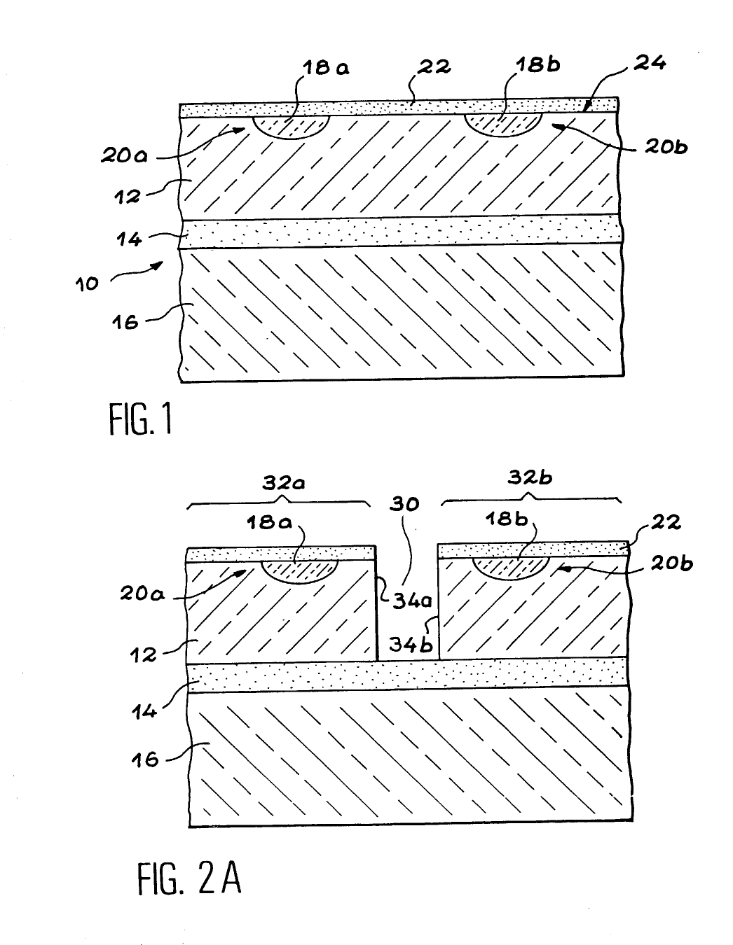

FIG. 1 shows a substrate 10 that comprises a surface layer 12 of semi conducting material, a buried layer 14 of electrically insulating material and a thick mechanical support layer 16. For example, the substrate 10 may be an SOI substrate. The semi conducting layers 12 and the insulating layer 14 are then made of silicon and silicon oxide (SiO₂) respectively. For example, the thickness of the semi conducting layer may be between 5 and 200 μm and the thickness of the insulating layer may vary between 0.1 μm and a few micrometers.

According to one variant, a thick single layer of electrically insulating material can be used as the insulating layer and the mechanical support layer.

In the example shown in FIG. 1, the semi conducting layer 12 is an N type silicon layer. Doped P type areas 18a and 18b are formed in the N type semi conducting layer in order to produce P—N junctions 20a, 20b.

In the remainder of the text, it is considered that each junction 20a, 20b forms an electronic component. In general, components formed in or on the semi conducting layer 12 are made using known micro-. electronic techniques that can, for example, include thermal oxidation, ionic implantation, thermal diffusion, material deposition steps and photoengraving steps. These techniques are well known in themselves and will not be described in further detail here.

A thin protection layer 22 made of silicon oxide is provided to protect the free upper face 24 of the semi conducting layer 12.

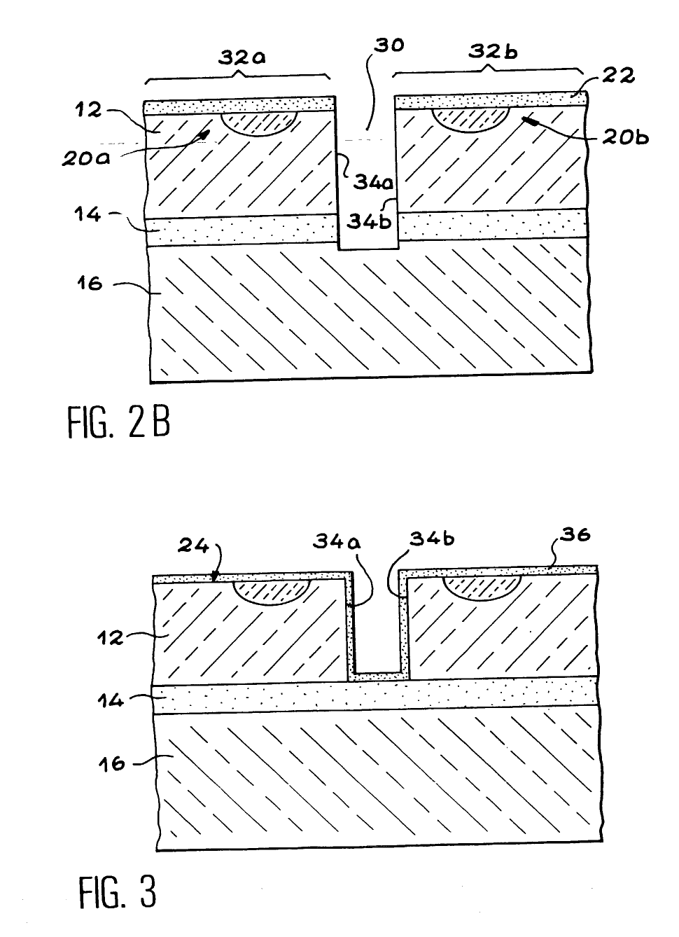

FIG. 2A shows production of a trench 30 that passes through the semi conducting layer 12. For example, the trench 30 may be formed by etching that may or may not be anisotropic. Its depth depends mainly on the thickness of the surface semi conducting layer 12 and may vary between a few microns and a few hundreds of microns.

Preferably, as shown in FIG. 2A, the semi conducting material is etched selectively with respect to the insulating material in order to stop the trench 30 at the interface between the semi conducting layer 12 and the insulating layer 14.

According to one variant illustrated in FIG. 2B, the trench 30 may pass through all or part of the insulating layer 14 to extend as far as the support layer 16.

FIGS. 2A and 2B show that the trench 30 is formed in an area of the substrate in which there are no components and extends approximately perpendicular to the substrate layers. However, this area may be doped; for example, it may be a superficially doped n or p type area. The two regions of the semi conducting layer separated by the trench are denoted as references 32a and 32b. The two regions are delimited laterally by the trench sides 34a, 34b.

The next step illustrated in FIG. 3 consists of cleaning the trench side 34a, 34b and preparing the trench for lining. The protection layer 22 that can be seen in the previous FIGURES is removed.

The step in which the trench is prepared may comprise doping of the trench sides and heat treatment to make the doping materials diffuse. Preparation may also include oxidation of the trench sides or formation of a material deposition, for example silicon oxide, to coat the sides of the trench. The material may be deposited by evaporation, spraying or by chemical vapour deposition (CVD), from silane gas.

In the example described, the steps (in order) are doping of the sides, thermal diffusion of the doping materials, removal of the protective layer 22, thermal oxidation to a thickness of the order of 0 to 1 μm and then deposition of silicon oxide over a comparable thickness.

The heat treatments may possibly be avoided if components 20a and 20b are sensitive to heat.

In FIG. 3, a coat of silicon oxide coats the sides 34a, 34b of the trench and covers the upper surface 24 of the semi conducting layer 12.

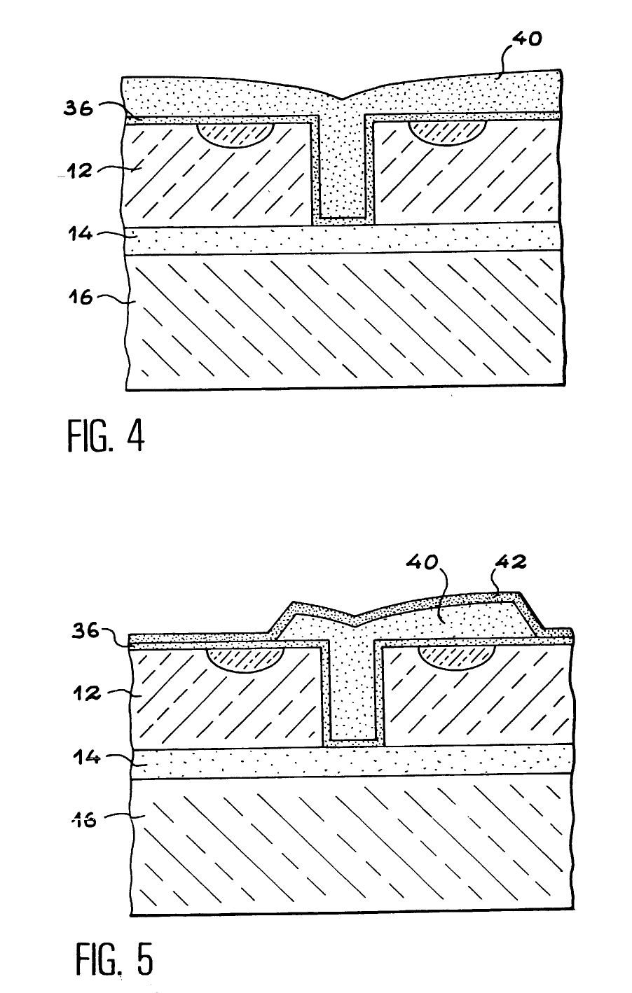

FIG. 4 shows filling of the trench with a filling material 40. The filling material is also deposited on the free surface of the substrate above the semi conducting layer 12.

In the example shown in the figure, the filling material is distributed on a whirler, in other words by rotating the substrate, and extends above the oxide layer 36.

The liquid filling material may be polymer based. For example, it may be a polyimide chosen for its good resistance at high temperature, or a polyacrylic or a silicon. Acrylics are used in preference to minimize mechanical stresses and their special feature is that they can be hardened by ultraviolet insolation. The fluidity of other filling materials is dependent mainly on their concentration of solvent before drying or poly-condensation.

Silicones such as methyl siloxanes can give highly insulating layers.

Sol-gel processes can also line the trench with other materials. Sol-gel materials then pass successively from a state in which colloidal particles are in suspension in a liquid (sol) to a gel state. Finally, a dense material may be obtained by drying.

Finally, insulating materials capable of melting under the effect of heat can also be placed in the trench, in the molten state, and then solidified.

Deposition of the filling material in the trench and possibly on the surface of the substrate may be repeated several times. The various deposition steps can thus be alternated with steps in which the filling material is hardened.

As mentioned above, hardening may be achieved by annealing, insolation or evaporation of the solvent.

Preferably, the filling material is chosen such that variations in volume between the fluid and solid phases are small, in order to limit stresses induced in the layer of semi conducting material 12.

The filling material may also be chosen for its good temperature resistance when subsequent component formation steps using heat treatments are envisaged.

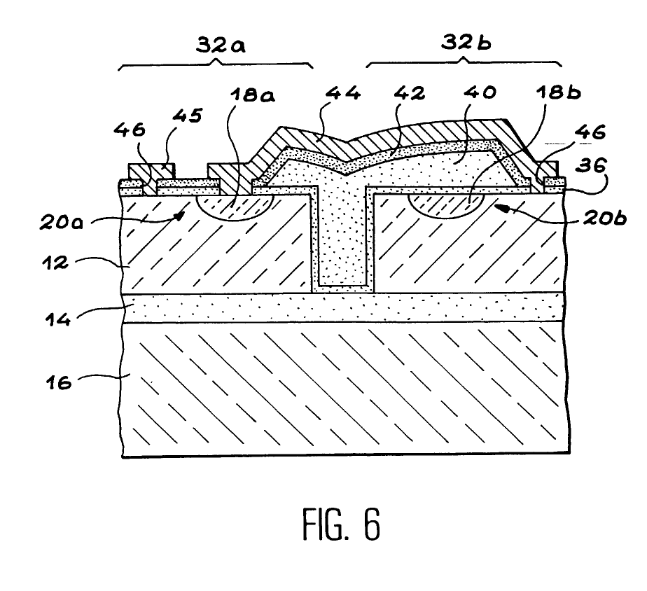

A subsequent step in the process is shown in FIG. 5. The layer of filling material extending to the surface of the substrate is shaped according to a determined pattern. For example, shaping may be done by etching according to a mask (not shown), keeping the insulating material particularly above the trench 30, in other words within an area in which there could be a high electric field when voltage is applied to regions of the semi conducting layer 12. The use of a filling material on the surface can give a greater thickness of insulation than is possible with conventional insulation. Furthermore, the trenches may be filled and the insulation may be formed on the surface at the same time in a single operation.

FIG. 5 also shows that an encapsulation layer 42, for example made of silicon oxide, is formed to cover the filling material 40 shaped on the surface of the substrate.

FIG. 6 shows a step in the manufacture of the interconnecting tracks 44, 45. This step includes the formation of openings 46 through the oxide insulating layers 36, 42 to expose portions of the substrate corresponding to parts of components, the deposition of a conducting layer, for example made of metal, and etching of this layer to form the tracks.

In the example shown in FIG. 6, an interconnecting track connects the P doped area 18a of the component 20a to an N doped area of the component 20b.

The formation of conducting tracks can also be used to complete manufacturing of integrated circuits in specific regions for which a final interconnecting stage was deliberately omitted during previous treatments.

### REFERENCED DOCUMENTS

(1) “Spin-On Glass for Dielectric Planarization” by Satish K. Gupta, pages 1-5, Allied-Signal Inc., Milpitas Calif.

1. Process for manufacturing a device comprising electronic components (20a, 20b) in regions (32a, 32b) of a layer of semi conducting material (12), these regions being insulated from each other, characterized in that it comprises the following steps:
a) formation of electronic components (30) in regions of a layer of semi conducting material (12) covering an electrically insulating layer (14),
b) formation of trenches passing through the layer of semi conducting material (12) from one side to the other in order to separate the said regions (32a, 32b),
c) filling of the trenches (30) with a fluid electrically insulating filling material that can be hardened, and
d) hardening of the said filling material,
e) formation of a layer of filling material above a free surface of the layer of semi conducting material (12), and formation of openings at least in the said layer in order to expose areas of the layer of semi conducting material,
f) formation of conducting tracks (44, 45) connecting components together extending over exposed areas, above the layer of semi conducting material.

2. Process according to claim 1, in which the steps of the process are executed in the indicated order.

3. Process according to claim 1, in which the trenches (30) are formed before the electronic components (20a, 20b).

4. Process according to claim 1, in which the depth P of the trenches exceeds 5 μm.

5. Process according to claim 1, in which the trenches (30) extend at least partly into the electrically insulating layer (14).

6. Process according to claim 1, in which the filling material (40) is chosen among polyimides, polyacrylics and silicones.

7. Process according to claim 6, in which the electrically insulating material is of the sol-gel type.

8. Process according to claim 1, in which at least one trench preparation treatment is carried out before the trenches are filled, the treatment being one of the following:
doping of the sides (34a, 34b) of the trenches (30),
thermal oxidation of the sides (34a, 34b) of the trenches,
lining of the sides (34a, 34b) of the trenches with a material deposit.

9. Process according to claim 1, in which filling of the trenches comprises an alternate sequence of steps in which the trenches are partially filled with the fluid electrically insulating material and steps in which the said material is hardened.

10. Process according to claim 1, also comprising shaping of the filling material.

11. Process according to claim 10, in which a photosensitive filling material is used and in which shaping is achieved by chemical development after insolation of the filling material through a mask.

12. Process according to claim 1, in which high voltage electronic components are made in step a).

13. Process according to claim 1, in which the filling layer of electrically insulating material is covered by an oxide layer (42), before openings are formed in it for the connection of tracks.

14. Device comprising a substrate with a layer of electrically insulating material (14) and a layer of semi conducting material (12) formed on the layer of electrically insulating material, in which insulating trenches (10) filled with an electrically insulating filling material pass through the layer of semi conducting material (12) from side to side and have trench sides (34a, 34b) that delimit regions (32a, 32b) of the layer of semi conducting material, the regions comprising electronic components (20a, 20b), and in which the filling material is chosen among insulating materials that are fluid in their initial state and can be hardened.

15. Device according to claim 14, in which the electrically insulating material is chosen among polymer materials, silicones and sol-gel type materials.

16. Device according to claim 14, in which the depth P of the trenches is greater than 5 μm.
